(19) United States
(12) Patent Application Publication
(10) Pub. No.: US 2008/0102644 A1
(43) Pub. Date: May 1, 2008

(54) METHODS FOR REMOVING PHOTORESIST FROM A SEMICONDUCTOR SUBSTRATE

(75) Inventors: Haruhiro Harry GOTO, Saratoga, CA (US); Weijie ZHANG, San Jose, CA (US); David CHEUNG, Foster City, CA (US)

Correspondence Address: INGRASSIA FISHER & LORENZ, P.C., 7150 E. CAMELBACK, STE. 325, SCOTTSDALE, AZ, 85251, US

(73) Assignee: NOVELLUS SYSTEMS, INC., San Jose, CA (US)

(21) Appl. No.: 11/554,709

(22) Filed: Oct. 31, 2006

(51) Int. Cl. H01L 21/302

(52) U.S. Cl. 438/710; 438/725; 438/714

(57) ABSTRACT

Methods for removing photoresist from a semiconductor substrate are provided. In accordance with an exemplary embodiment of the invention, a method for removing a photoresist from a semiconductor substrate comprises the steps of exposing the semiconductor substrate and the photoresist to a first plasma formed from oxygen, forming an oxide layer on exposed regions of the semiconductor substrate, and subjecting the photoresist to a second plasma formed from oxygen and a fluorine-comprising gas, wherein the first plasma is not the second plasma.

### FIELD OF THE INVENTION

The present invention generally relates to semiconductor processing, and more particularly relates to methods for removing photoresist from a semiconductor substrate.

### BACKGROUND OF THE INVENTION

Photoresist materials are used in a variety of semiconductor processing operations, including material patterning and impurity dopant implantation. Commercial photoresists are polymeric coatings that are designed to change properties upon exposure to light during a photolithography process. Then, either the exposed or unexposed regions of the coating can be selectively removed to reveal the substrate beneath. The photoresist also “resists” the actual circuit formation step, i.e. etching, ion implantation, metal deposition, etc., thereby protecting the substrate beneath where required. The patterned photoresist can be used to define features in substrates by etching, as well as to deposit materials onto, or implant materials into, substrates.

During impurity dopant implantation, as illustrated in FIG. 1, an impurity dopant species, illustrated by arrows 10, typically boron, arsenic or phosphorous, is implanted into an underlying semiconductor substrate 12 using a patterned photoresist 14 as an implantation mask and using a plasma comprising a dose of the species. Presently, a “low dose” implantation comprises a plasma implantation using a species concentration of no greater than 1×10¹² cm⁻² and “high dose” implantation comprises plasma implantation using a species concentration of no less than 1×10¹³ cm⁻², although as technology proceeds, “low dose” implantation may utilize higher and higher species concentrations. Recently, plasma-assisted doping (“PLAD”) using very high species concentrations of 1×10¹⁶ cm⁻² or more has been used to form ultra-shallow junction devices.

During “high dose” implantation, the photoresist is subjected to high dose ion implantation which drives the implanted species into the photoresist. Such ion implanted photoresist exhibits characteristics that are quite different from the original photoresist. This modified surface layer of the photoresist is often referred to as the implant crust or, simply, crust. For example, boron has a high chemical activity and tends to react with ambient moisture to form a B₂O₃ crust, which is difficult to remove by present-day methods.

Once the implantation has concluded, the photoresist is removed from the semiconductor substrate so that semiconductor fabrication may proceed. After a “low dose” implantation, the photoresist can be stripped by a high temperature (>250C) oxygen plasma according to the following mechanism:

O₂+nCₓH_{y}(photoresist)→CO₂+H₂O.

After a “high dose” implantation, however, due to the low volatility characteristic of the implant species, the crust can be very difficult to remove. The problem is compounded after a PLAD process because the higher the implant doping concentration, the more difficult it is to remove the photoresist crust. A fluorine-comprising component typically is added to the high temperature oxygen-based plasma to remove the photoresist and any implant crust residue on the surface of the substrate. However, as illustrated in FIG. 2, the fluorine radicals of the fluorine-comprising plasma can etch a silicon-based substrate 20 at a high rate resulting in a significant loss, illustrated by arrows 22, of the substrate. The more difficult it is to remove the photoresist crust, the more fluorine is needed to remove the crust; however, the more fluorine used to remove the crust, the more material is lost from the substrate. For the next smaller generation of semiconductor devices, that is, 45 nm nodes and even smaller, such substrate loss results in damage to the substrate and, hence, reduces device yield.

Accordingly, it is desirable to provide a method for removing a photoresist from a semiconductor substrate after a high or very high impurity dopant implantation process. In addition, it is desirable to provide a method for removing the photoresist without significant substrate loss. Furthermore, other desirable features and characteristics of the present invention will become apparent from the subsequent detailed description of the invention and the appended claims, taken in conjunction with the accompanying drawings and this background of the invention.

### BRIEF DESCRIPTION OF THE DRAWINGS

The present invention will hereinafter be described in conjunction with the following drawing figures, wherein like numerals denote like elements, and wherein:

FIG. 1 is side view of a semiconductor substrate with a patterned photoresist undergoing impurity dopant implantation;

FIG. 2 is a schematic illustration of the loss of semiconductor substrate resulting from the removal of the patterned photoresist of FIG. 1;

FIG. 3 is a method for removing photoresist from a semiconductor substrate in accordance with an exemplary embodiment of the present invention;

FIG. 4 is side view of a semiconductor substrate with a patterned photoresist undergoing impurity dopant implantation;

FIG. 5 is a side view of the semiconductor substrate of FIG. 4 after exposure to a first plasma in accordance with the method of FIG. 3; and

FIG. 6 is a side view of the semiconductor substrate of FIG. 5 after exposure to a second plasma in accordance with the method of FIG. 3.

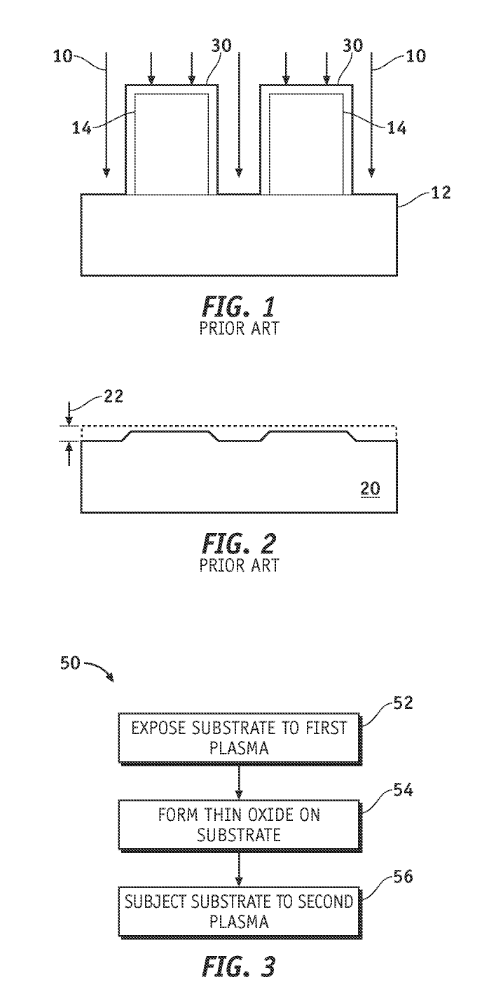

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

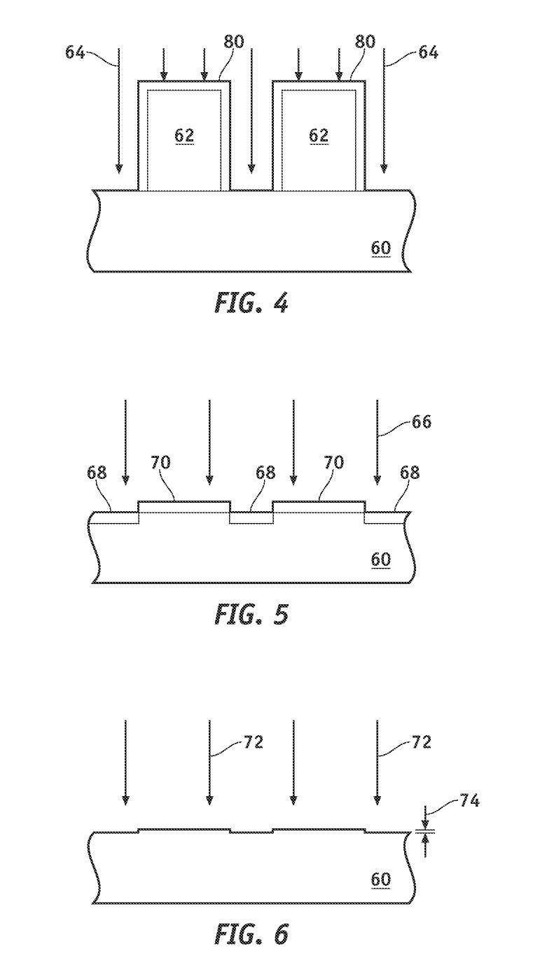

FIG. 3 illustrates a method 50 for removing a photoresist from a semiconductor substrate, in accordance with an exemplary embodiment of the present invention. Referring momentarily to FIG. 4, the method is performed after a patterned photoresist 62 is formed on a semiconductor substrate 60 that is subjected to the implantation of impurity dopants, represented by arrows 64, using patterned photoresist 62 as an implantation mask. The semiconductor substrate 60 is a silicon substrate wherein the term “silicon substrate” is used herein to encompass the relatively pure silicon materials typically used in the semiconductor industry as well as silicon admixed with other elements such as germanium, carbon, and the like. Alternatively, the semiconductor substrate can be silicon oxide, silicon nitride or other silicon-based semiconductor material. Semiconductor substrate 60 may be a bulk silicon wafer, or may be a thin layer of silicon on an insulating layer (commonly know as silicon-on-insulator or SOI) that, in turn, is supported by a carrier wafer. The patterned photoresist can be any photoresist polymer utilized in semiconductor technology and can be patterned using any conventional lithography method, such as, for example, I-line or deep UV lithography. The impurity dopants typically include arsenic, phosphorous, or boron, although the semiconductor substrate may also be implanted with any other impurity dopant used in the semiconductor industry. The implantation may be a “low dose” implantation, although the method 50 is particularly suitable for removing photoresist after a “high dose” implantation or a very high dose implantation, that is, with species concentrations no less than about 1×10¹³ cm⁻². As described above, the implanted dopants may cause a crust 80 to form on the outside surfaces of the patterned photoresist.

Referring back to FIG. 3, the method 50 utilizes the step of exposing the semiconductor substrate to a first plasma (step 52). In an exemplary embodiment of the invention, the first plasma is formed from oxygen and a forming gas. The forming gas comprises hydrogen and an inert dilutant, such as, for example, nitrogen, helium, or the like, or a combination thereof. In an exemplary embodiment of the invention, the forming gas is about 0.5 to about 10 molar percent (%) hydrogen. In a preferred embodiment of the invention, the forming gas is about 4 to about 6% hydrogen and in a more preferred embodiment of the invention, the forming gas is about 5% hydrogen. As illustrated in FIG. 5, the oxygen, illustrated by arrows 66, is present in the first plasma to strip the photoresist via the following mechanism:

O₂+nCₓH_{y}(photoresist)→CO₂+H₂O.

The photoresist is substantially removed, leaving only a photoresist residue 70 on the semiconductor substrate. The method also includes the step of forming a thin oxide 68 on the semiconductor substrate 60 (step 54) using the oxygen and forming gas in the first plasma. In accordance with this embodiment, this oxide is sufficiently thick so that when the substrate is exposed to fluorine radicals, as described in more detail below, the loss of silicon is significantly minimized. In an exemplary embodiment, the oxide has a thickness in the range of about 0 to about 5 nm, preferably about 0 to about 2 nm.

The forming gas in the first plasma serves as a reducing agent to reduce the crust of the photoresist. In particular, the hydrogen quite effectively reduces boron oxide to more volatile species via the mechanism:

B₂O₃+H⁺→BₓH_{y}+O_{z}.

These volatile species can be more easily removed from the semiconductor substrate than the un-reduced crust. In an exemplary embodiment of the invention, the first plasma comprises an O₂:forming gas ratio in the range of 0:1 to 1:0. In a preferred embodiment of the invention, the first plasma comprises an O₂:forming gas ratio in the range of about 19:1 to about 1:19. In a more preferred embodiment, the first plasma comprises an O₂:forming gas ratio of about 4:1.

In an exemplary embodiment of the invention, the semiconductor substrate is maintained at or heated to a temperature in the range of about 16° C. (i.e., room temperature) to about 300° C. during exposure to the first plasma. The time during which the semiconductor substrate is exposed to the first plasma is a function of the thickness of the photoresist and the thickness and composition of the crust on the photoresist. The semiconductor also is maintained at a pressure in the range of about 1 mTorr to about 1 atm, preferably about 0.1 Torr to about 10 Torr.

After the semiconductor substrate has been exposed to the first plasma for a time sufficient to remove a portion of the photoresist, preferably a substantial portion of the photoresist, and permit an oxide layer to form on the substrate, the substrate then is subjected to a second plasma (step 56). In an exemplary embodiment of the invention, the second plasma is formed from oxygen, a forming gas or an inert dilutant, such as, for example, nitrogen or helium, and a fluorine-comprising gas that serves as a source of fluorine radicals. The fluorine-comprising gas can be nitrogen trifluoride (NF₃), sulfur hexafluoride (SF₆), hexafluoroethane (C₂F₆), tetrafluoromethane (CF₄), trifluoromethane (CHF₃), difluoromethane (CH₂F₂), octofluoropropane (C₃F₈), octofluorocyclobutane (C₄F₈), octofluoro[1-]butane (C₄F₈), octofluoro[2-]butane (C₄F₈), octofluoroisobutylene (C₄F₈), fluorine (F₂), and the like. In an exemplary embodiment of the invention, the second plasma is formed from oxygen, forming gas or nitrogen, and CF₄. In a preferred embodiment of the invention, the second plasma is formed from oxygen present in the range of about 10% to about 100%, forming gas or nitrogen present in the range of about 0% to about 50%, and CF₄ present in the range of about 0% to about 20%. In a more preferred embodiment of the invention, the second plasma is formed from oxygen, forming gas or nitrogen, and CF₄ in a ratio of oxygen: forming gas or nitrogen:CF₄ of about 16:2:0.05. Forming gas may allow for more accurate control of silicon loss because the hydrogen bonds with fluorine radicals. As illustrated in FIG. 6, the second plasma, illustrated by arrows 72, removes the photoresist residue and, at a much slower rate, the thin oxide layer while minimizing the silicon consumed, illustrated by arrows 74, during the second plasma process.

In an exemplary embodiment of the invention, the semiconductor substrate is maintained at or heated to a temperature in the range of about 16° C. (i.e., room temperature) to about 300° C. during exposure to the second plasma. The time during which the semiconductor substrate is exposed to the second plasma is a function of the thickness of the photoresist residue after the first plasma process. The semiconductor also is maintained at a pressure in the range of about 1 mTorr to about 1 atm, preferably about 0.1 Torr to about 10 Torr. It will be understood that exposure to the first plasma and exposure to the second plasma can be performed as two discrete steps, for example, with a purge step performed therebetween, or can be performed as one continuous plasma flow step with the composition of the continuous plasma flow changing from the composition of the first plasma to the composition of the second plasma.

The method can be performed in any suitable plasma apparatus, such as, for example, a strip unit dedicated to stripping photoresist from semiconductor wafers. For instance, the invention may be implemented on a Gamma® tool manufactured by Novellus Systems, Inc. of San Jose, Calif. The Novellus Gamma® tool supports the sequential processing of up to six wafers in a common process chamber and is generally used for the purposes of resist strip, clean and dielectric and silicon etch applications. However, it should be appreciated that the method of the present invention is not limited to the Novellus Gamma® platform, but can be performed in other strip or etch process tool platforms.

The following is an example of method, such as method 50, for removing a patterned photoresist from a semiconductor substrate implanted with boron ions. After a patterned photoresist is formed on the semiconductor substrate, boron ions are implanted into the substrate using a very high dose implant concentration of 5×10¹⁶ cm⁻². After the very high dose implantation of the semiconductor substrate, the semiconductor substrate is exposed to a first plasma formed from oxygen gas flowing at about 16 standard liters per minute (slm) and from a forming gas flowing at about 4 slm. The forming gas comprises 5% hydrogen and 95% nitrogen. The semiconductor substrate is heated to a temperature of about 160° C. and the semiconductor substrate is exposed to the first plasma for about 240 seconds. After exposure to the first plasma, the semiconductor substrate is exposed to a second plasma formed from oxygen gas flowing at about 18 slm, nitrogen gas flowing at about 1.5 slm, and CF₄ gas flowing at about 0.01 slm. The semiconductor substrate is heated to a temperature of about 160° C. and the semiconductor substrate is exposed to the first plasma for about 60 seconds. The exemplary method achieves removal of the photoresist from the substrate while minimizing the amount of material lost from the substrate. This example is for illustrative purposes and is not meant in any way to limit the scope of the invention. For example, if the semiconductor substrate had been implanted with arsenic ions instead of boron ions, it may be desirable to use a CF₄ gas flow of less or significantly less than about 0.01 slm.

Accordingly, various embodiments of a method for removing a photoresist from a semiconductor substrate have been provided. The method results in removal of the photoresist from the substrate while minimizing the amount of substrate consumed during the removal process. While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A method for removing a photoresist from a semiconductor substrate, the method comprising the steps of:
exposing the semiconductor substrate and the photoresist to a first plasma formed from oxygen;
forming an oxide layer on exposed regions of the semiconductor substrate;
subjecting the photoresist to a second plasma formed from oxygen and a fluorine-comprising gas, wherein the first plasma is not the second plasma.

2. The method of claim 1, wherein the step of exposing the semiconductor substrate and the photoresist to a first plasma and the step of forming an oxide layer on exposed regions of the semiconductor substrate are performed simultaneously.

3. The method of claim 1, wherein the step of exposing the semiconductor substrate and the photoresist to a first plasma comprises the step of exposing the semiconductor substrate and the photoresist to a first plasma formed from oxygen and a forming gas comprising hydrogen.

4. The method of claim 3, wherein the step of exposing the semiconductor substrate and the photoresist to a first plasma formed from oxygen and a forming gas comprising hydrogen comprises the step of exposing the semiconductor substrate and the photoresist to a first plasma formed from oxygen and a forming gas comprising about 4% to about 6% hydrogen.

5. The method of claim 3, wherein the step of exposing the semiconductor substrate and the photoresist to a first plasma formed from oxygen and a forming gas comprising hydrogen comprises the step of exposing the semiconductor substrate and the photoresist to a first plasma formed from oxygen and forming gas present in a oxygen:forming gas ratio in the range of about 19:1 to about 1:19.

6. The method of claim 5, wherein the step of exposing the semiconductor substrate and the photoresist to a first plasma formed from oxygen and forming gas present in a oxygen:forming gas ratio in the range of about 19:1 to about 1:19 comprises the step of exposing the semiconductor substrate and the photoresist to a first plasma formed from oxygen and forming gas present in a oxygen:forming gas ratio of about 4:1.

7. The method of claim 1, wherein the step of exposing the semiconductor substrate to a first plasma formed from oxygen comprises the step of exposing the semiconductor substrate to a first plasma formed from oxygen with the semiconductor substrate at a temperature in the range of about 16° C. to about 300° C.

8. The method of claim 1, wherein the step of subjecting the photoresist to a second plasma formed from oxygen and a fluorine-comprising gas comprises the step of subjecting the photoresist to a second plasma formed from oxygen, a fluorine-comprising gas, and an inert dilutant or a forming gas comprising hydrogen.

9. The method of claim 8, wherein the step of subjecting the photoresist to a second plasma formed from oxygen, a fluorine-comprising gas, and an inert dilutant or a forming gas comprising hydrogen comprises the step of subjecting the photoresist to a second plasma formed from oxygen present in the range of about 10% to about 100%, forming gas or nitrogen present in the range of about 0% to about 50%, and CF₄ present in the range of about 0% to about 20%.

10. The method of claim 9, wherein the step of the step of subjecting the photoresist to a second plasma formed from oxygen present in the range of about 10% to about 100%, forming gas or nitrogen present in the range of about 0% to about 50%, and CF₄ present in the range of about 0% to about 20% comprises the step of subjecting the photoresist to a second plasma formed from oxygen, nitrogen, and CF₄ present in the ratio of about 16:2:0.05, respectively.

11. The method of claim 1, wherein the step of subjecting the photoresist to a second plasma formed from oxygen and a fluorine-comprising gas comprises the step of subjecting the photoresist to a second plasma formed from oxygen and a fluorine-comprising gas with the semiconductor substrate at a temperature in the range of about 16° C. to about 300° C.

12. The method of claim 1, wherein the step of subjecting the photoresist to a second plasma is performed after but continuous with the step of exposing the semiconductor substrate and the photoresist to a first plasma.

13. A method for fabricating a semiconductor device, the method comprising the steps of:
implanting impurity dopants into a semiconductor substrate using a patterned photoresist as an implantation mask;
providing a first plasma formed from oxygen and a forming gas to the semiconductor substrate and the photoresist; and
exposing the photoresist to a second plasma formed from a source of fluorine radicals.

14. The method of claim 13, wherein the step of providing a first plasma formed from oxygen and a forming gas to the semiconductor substrate and the photoresist comprises the step of providing a first plasma formed of oxygen and a forming gas that comprises about 4% to about 6% hydrogen.

15. The method of claim 13, wherein the step of providing a first plasma formed from oxygen and a forming gas to the semiconductor substrate and the photoresist comprises the step of providing a first plasma formed from oxygen and a forming gas present in the ratio of about 4:1.

16. The method of claim 13, wherein the step of exposing the photoresist to a second plasma formed from a source of fluorine radicals comprises the step of exposing the photoresist to a second plasma formed from a material selected from the group consisting of nitrogen trifluoride, sulfur hexafluoride, hexafluoroethane, tetrafluoromethane, trifluoromethane, difluoromethane, octofluoropropane, octofluorocyclobutane (C₄F₈), octofluoro[1-]butane (C₄F₈), octofluoro[2-]butane (C₄F₈), octofluoroisobutylene (C₄F₈), and fluorine.

17. The method of claim 13, wherein the step of exposing the photoresist to a second plasma formed from a source of fluorine radicals comprises the step of exposing the photoresist to a second plasma formed from oxygen, an inert dilutant or a forming gas comprising hydrogen, and a source of fluorine radicals.

18. The method of claim 17, wherein the step of exposing the photoresist to a second plasma formed from oxygen, an inert dilutant or a forming gas comprising hydrogen, and a source of fluorine radicals comprises the step of exposing the photoresist to a second plasma formed from about 10% to about 100% oxygen, 0% to about 50% nitrogen or forming gas, and 0% to about 20% CF₄.

19. The method of claim 13, wherein the step of exposing the photoresist to a second plasma formed from a source of fluorine radicals is performed after but continuous with the step of providing a first plasma formed from oxygen and a forming gas to the semiconductor substrate and the photoresist.

20. A method for removing a photoresist from a semiconductor substrate, the method comprising the steps of:
removing a first portion of the photoresist using a first plasma;
forming an oxide layer on the semiconductor substrate;
removing a remainder of the photoresist using a second plasma, wherein the first plasma is not the second plasma.

21. The method of claim 20, wherein the step of removing a first portion of the photoresist using a first plasma and the step of forming an oxide layer on the semiconductor substrate are performed simultaneously.

22. The method of claim 20, wherein the step of removing a first portion of the photoresist using a first plasma comprises the step of removing a first portion of the photoresist using a first plasma formed from oxygen and a forming gas comprising hydrogen.

23. The method of claim 22, wherein the step of removing a first portion of the photoresist using a first plasma formed from oxygen and a forming gas comprising hydrogen comprises the step of removing a first portion of the photoresist using a first plasma formed from oxygen and forming gas present in a oxygen:forming gas ratio in the range of about 19:1 to about 1:19.

24. The method of claim 23, wherein the step of removing a first portion of the photoresist using a first plasma formed from oxygen and forming gas present in a oxygen: forming gas ratio in the range of about 19:1 to about 1:19 comprises the step of removing a first portion of the photoresist using a first plasma formed from oxygen and forming gas present in a oxygen:forming gas ratio of about 4:1.

25. The method of claim 20, wherein the step of removing a remainder of the photoresist using a second plasma comprising the step of removing a remainder of the photoresist using a second plasma formed from oxygen, nitrogen or a forming gas comprising hydrogen, and fluorine-comprising gas.

26. The method of claim 25, wherein the step of removing a remainder of the photoresist using a second plasma formed from oxygen, nitrogen or a forming gas comprising hydrogen, and fluorine-comprising gas comprises the step of removing a remainder of the photoresist using a second plasma formed from about 10% to about 100% oxygen, 0% to about 50% nitrogen or forming gas, and 0% to about 20% CF₄.
